(19) United States
(12) Patent Application Publication
(10) Pub. No.: US 2016/0307975 A1
(43) Pub. Date: Oct. 20, 2016

(54) OLED DISPLAY ELEMENT

(71) Applicant: Shenzhen China Star Optoelectronics Technology Co. Ltd., Shenzhen City (CN)

(72) Inventors: Xiaowen Lv, Shenzhen City (CN); Longqiang Shi, Shenzhen City (CN)

(21) Appl. No.: 14/763,832

(22) PCT Filed: May 22, 2015
(86) PCT No.: PCT/CN2015/079540

§ 371 Date: Jul. 28, 2015

(30) Foreign Application Priority Data
Apr. 13, 2015 (CN) 201510173285.3

(51) Int. Cl. H01L 27/32

(52) U.S. Cl. CPC H01L 27/3246

(57) ABSTRACT

The present invention provides an OLED display element, comprising: a substrate (1), a pixel electrode (2), an organic light emitting layer (3) and a common electrode (4) sequentially stacked on the substrate (1) in each pixel area, and a pixel isolation layer (5) having a plurality of apertures, and the aperture is formed with pixel isolation layer side walls (51) around, and each aperture corresponds to one pixel area; material of the pixel isolation layer (5) is inorganic material, and the pixel isolation layer side wall (51) comprises a straight line part (511), and a curved part (512) connected to the straight line part (511) from top to bottom, which can solve the deterioration issue of the organic light emitting layer (3) caused by the pixel isolation layer side walls (51) to prevent that gaps of the organic light emitting layer (3) and the common electrode (4) generate at positions of the pixel isolation layer side walls (51) and to avoid the short circuit of the common electrode (4) and the pixel electrode (2), i.e. the cathode and the anode of the OLED display element for improving the display effect.

### FIELD OF THE INVENTION

The present invention relates to a display technology field, and more particularly to an OLED display element.

### BACKGROUND OF THE INVENTION

The Organic Light Emitting Display (OLED) element does not only possess extremely excellent display performance but also properties of self-illumination, simple structure, ultra thin, fast response speed, wide view angle, low power consumption and capability of realizing flexible display, and therefore is considered as “dream display”. It has been favored by respective big display makers and has become the main selection of the third generation display element.

The OLED display element is a self-emitting type display device, and generally comprises a pixel electrode and a common electrode respectively employed as being the anode and the cathode, and an organic light emitting layer positioned between the pixel electrode and the common electrode. As the proper voltages are applied to the anode and the cathode, the organic light emitting layer emits light. The organic light emitting layer comprises a Hole Injection Layer positioned on the anode, a Hole Transporting Layer positioned on the Hole Injection Layer, a light emitting layer positioned on the Hole Transporting Layer, an Electron Transport Layer positioned on the light emitting layer and an Electron Injection Layer positioned on the Electron Transport Layer. The lighting principle is that under certain voltage driving, the Electron and the Hole are respectively injected into the Electron Injection Layer and Hole Electron Injection Layer from the cathode and the anode. The Electron and the Hole respectively migrate from the Electron Transporting Layer and Hole Transporting Layer to the Emitting layer and bump into each other in the Emitting layer to form an exciton to excite the emitting molecule. The latter can illuminate after the radiative relaxation.

Generally, the OLED display element comprises a plurality of pixel areas arranged in array, and a pixel isolation layer comprising a plurality of apertures isolates each pixel area from other pixel areas, and each aperture corresponds to one pixel area, and the aforesaid pixel electrode and the organic light emitting layer are correspondingly positioned inside the aperture, and the common electrode covers the organic light emitting layer and the pixel isolation layer in each pixel area.

Because the organic light emitting layer is formed by organic material which is highly sensitive to the water vapor and oxygen. Therefore, the deterioration can easily occur due to the invasion of the water vapor and oxygen. In prior art, the pixel isolation layer is manufacture by organic material. It is found that as the pixel isolation layer, which is organic material has an interface contacting the organic light emitting layer, the water vapor and oxygen in the pixel isolation layer will diffuse to the organic light emitting layer from the interface to cause the change of the electron state in the organic light emitting layer. The ideal electronic filed light emitting property will lose to deteriorate the organic light emitting layer and influence the display effect. For improving the issue due to the pixel isolation layer, which is organic material, the skill that the inorganic material of which the contents of the water vapor and oxygen are lower is employed to manufacture the pixel isolation layer. However, as employed the inorganic material to manufacture the pixel isolation layer, the side walls constructing the aperture of the pixel isolation layer are up-right close to 90 degrees relative to the substrate and cause that the thicknesses of the organic light emitting layer and the common electrode correspondingly at the positions of the side walls are obviously thinner and even gaps generate. The water vapor and oxygen will enter the organic light emitting layer from where the common electrode is thinner or the gaps to cause the lighting property deterioration of the organic light emitting layer. Therefore, as the gaps of the organic light emitting layer generate at the positions of the side walls, the distance between the common electrode and the pixel electrode is extremely close and results in short circuit of the two electrodes and damage to the organic light emitting layer.

### SUMMARY OF THE INVENTION

An objective of the present invention is to provide an OLED which can solve the deterioration issue of the organic light emitting layer caused by the pixel isolation layer side walls to prevent that gaps of the organic light emitting layer and the common electrode generate at positions of the pixel isolation layer side walls and to avoid the short circuit of the common electrode and the pixel electrode, i.e. the cathode and the anode of the OLED display element for improving the display effect.

For realizing the aforesaid objectives, the present invention provides an OLED display element, comprising:

a substrate;

a plurality of pixel areas arranged in array on the substrate, and each pixel area comprises a pixel electrode, an organic light emitting layer and a common electrode sequentially stacked on the substrate;

a pixel isolation layer having a plurality of apertures, and the pixel isolation layer isolates each pixel area from other pixel areas, and the aperture is formed with pixel isolation layer side walls around, and each aperture corresponds to one pixel area;

wherein the pixel electrode and the organic light emitting layer are inside the aperture, and the organic light emitting layer covers the pixel isolation layer side walls, and the common electrode covers the organic light emitting layer and an upper surface of the pixel isolation layer;

material of the pixel isolation layer is inorganic material, and the pixel isolation layer side wall comprises a straight line part, and a curved part connected to the straight line part from top to bottom; the straight line part is perpendicular with the substrate, and a height of the straight line part is smaller than a height of the curved part, and at least, an included angle between a tangent plane where a portion of the curved part is and the substrate is smaller than 85°.

The curved part recesses inward relative to the pixel isolation layer.

The curved part embosses outward relative to the pixel isolation layer.

Material of the pixel isolation layer is Silicon Nitride.

The pixel isolation layer is composed by stacking a plurality of Silicon Nitride layers with various component ratios.

The pixel isolation layer is manufactured by a plasma CVD process, and apertures of the pixel isolation layer are manufactured by an etching process.

The pixel electrode is an anode of the OLED display element, and the common electrode is a cathode of the OLED display element.

Material of the pixel electrode is metal oxide with high work function, and material of the common electrode is metal with high electric conductivity and low work function.

The pixel electrode is a cathode of the OLED display element, and the common electrode is an anode of the OLED display element.

Material of the pixel electrode is metal with high electric conductivity and low work function, and material of the common electrode is metal oxide with high work function.

The present invention further provides an OLED display element, comprising:

a substrate;

a plurality of pixel areas arranged in array on the substrate, and each pixel area comprises a pixel electrode, an organic light emitting layer and a common electrode sequentially stacked on the substrate;

a pixel isolation layer having a plurality of apertures, and the pixel isolation layer isolates each pixel area from other pixel areas, and the aperture is formed with pixel isolation layer side walls around, and each aperture corresponds to one pixel area;

wherein the pixel electrode and the organic light emitting layer are inside the aperture, and the organic light emitting layer covers the pixel isolation layer side walls, and the common electrode covers the organic light emitting layer and an upper surface of the pixel isolation layer;

material of the pixel isolation layer is inorganic material, and the pixel isolation layer side wall comprises a straight line part, and a curved part connected to the straight line part from top to bottom; the straight line part is perpendicular with the substrate, and a height of the straight line part is smaller than a height of the curved part, and at least, an included angle between a tangent plane where a portion of the curved part is and the substrate is smaller than 85°;

wherein the curved part recesses inward relative to the pixel isolation layer;

wherein material of the pixel isolation layer is Silicon Nitride;

wherein the pixel isolation layer is composed by stacking a plurality of Silicon Nitride layers with various component ratios.

The benefits of the present invention are: the present invention provides an OLED display element. On one hand, the inorganic material is employed to form the pixel isolation layer to tremendously reduce the water vapor and oxygen diffused from the pixel isolation layer side wall to the organic light emitting layer, and on the other hand, the pixel isolation layer side wall positions the straight line part and the curved part from top to bottom, and the height of the straight line part is smaller than the height of the curved part. At least, the included angle between a tangent plane where the portion of the curved part is and the substrate is smaller than 85° to make the thicknesses of the organic light emitting layer covering the pixel isolation layer side walls and the common electrode covering the organic light emitting layer uniform to prevent that the gaps of the organic light emitting layer and the common electrode generate at positions of the pixel isolation layer side walls and that the water vapor and oxygen permeate into the organic light emitting layer. The deterioration issue of the organic light emitting layer caused by the pixel isolation layer side walls can be solved to avoid the short circuit of the common electrode and the pixel electrode, i.e. the cathode and the anode of the OLED display element for improving the display effect and promoting the usage lifetime of the OLED display element.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a sectional structure diagram of one pixel area in an OLED display element according to the present invention;

FIG. 2 is a sectional diagram of the first embodiment of appearance of the pixel isolation layer side wall in accordance with FIG. 1;

FIG. 3 is a sectional diagram of the second embodiment of appearance of the pixel isolation layer side wall in accordance with FIG. 1.

### DETAILED DESCRIPTION OF PREFERRED EMBODIMENTS

For better explaining the technical solution and the effect of the present invention, the present invention will be further described in detail with the accompanying drawings and the specific embodiments.

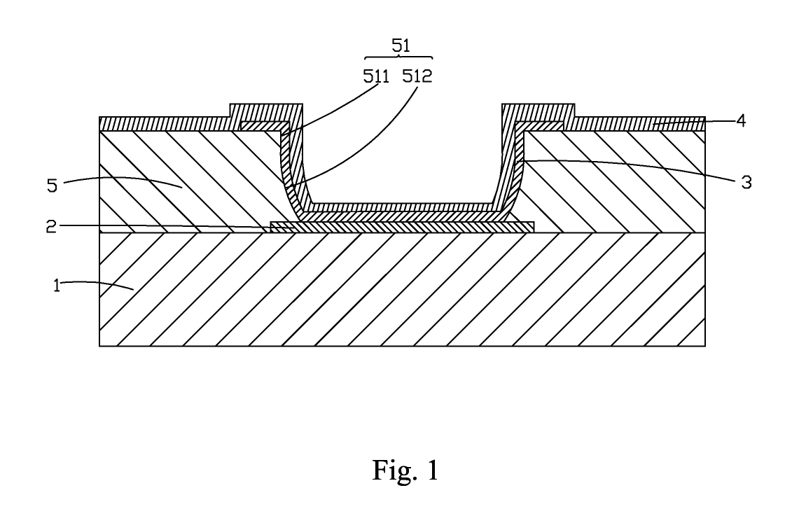

Please refer to FIG. 1. The present invention provides an OLED display element, comprising:

a substrate 1;

a plurality of pixel areas arranged in array on the substrate 1, and each pixel area comprises a pixel electrode 2, an organic light emitting layer 3 and a common electrode 4 sequentially stacked on the substrate 1;

and a pixel isolation layer 5 having a plurality of apertures, and the pixel isolation layer 5 isolates each pixel area from other pixel areas, and the aperture is formed with pixel isolation layer side walls 51 around, and each aperture corresponds to one pixel area.

The pixel electrode 2 and the organic light emitting layer 3 are inside the aperture, and the organic light emitting layer 3 covers the pixel isolation layer side walls 51, and the common electrode 4 covers the organic light emitting layer 3 and an upper surface of the pixel isolation layer 5.

Material of the pixel isolation layer 5 is inorganic material, and the pixel isolation layer side wall 51 comprises a straight line part 511, and a curved part 512 connected to the straight line part 511 from top to bottom; the straight line part 511 is perpendicular with the substrate 1, and a height of the straight line part 511 is smaller than a height of the curved part 512, and at least, an included angle between a tangent plane where a portion of the curved part 512 is and the substrate 1 is smaller than 85°.

Significantly, under the premise that at least, an included angle between a tangent plane where a portion of the curved part 512 is and the substrate 1 is smaller than 85° is ensured, it does not demand that the tangent planes of all positions where the curved part 512 is have to construct an included angle smaller than 85° with the substrate 1.

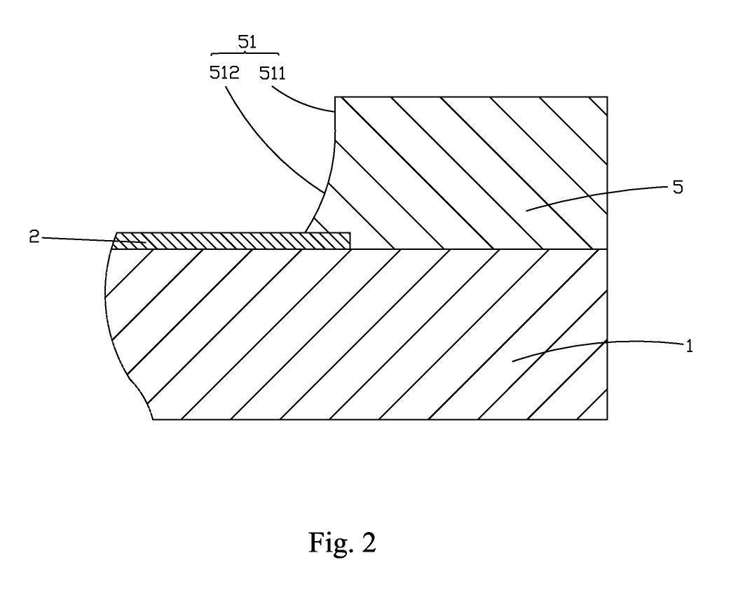

FIG. 2 shows the first embodiment of appearance of the pixel isolation layer side wall 51. The curved part 512 recesses inward relative to the pixel isolation layer 5. An included angle between a tangent plane where a portion of the curved part 512 is and the substrate 1 is smaller than 85°. The curved part 512 and the straight line part 511 are connected in a tangent way.

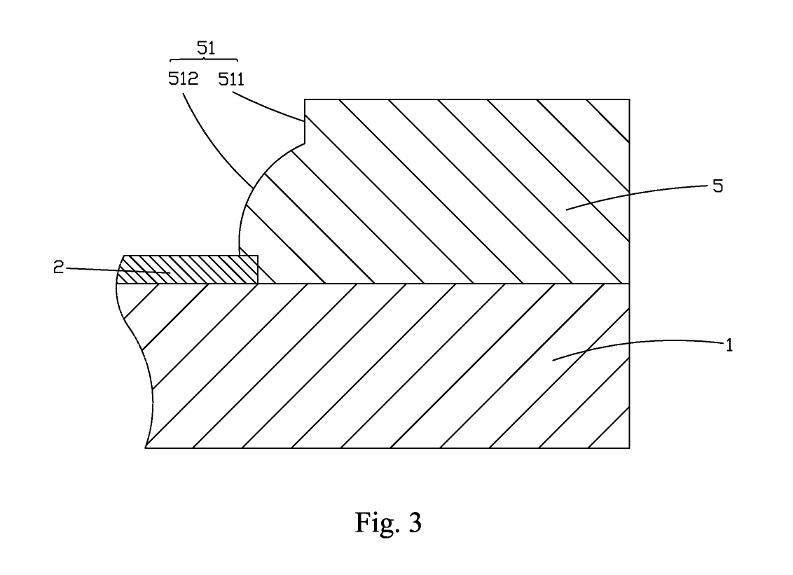

FIG. 3 shows the second embodiment of appearance of the pixel isolation layer side wall 51. The curved part 512 embosses outward relative to the pixel isolation layer 5. An included angle between a tangent plane where a portion of the curved part 512 is and the substrate 1 is smaller than 85°. The curved part 512 and the straight line part 511 are connected in a joining way.

The material of the pixel isolation layer 5 is inorganic material of which the contents of the water vapor and oxygen are lower. It can tremendously reduce the water vapor and oxygen diffused from the pixel isolation layer side wall 51 to the organic light emitting layer 3; the appearance of the pixel isolation layer side wall 51 constructed by the straight line part 511 and the curved part 512 can make the thicknesses of the organic light emitting layer 3 covering the pixel isolation layer side walls 51 and the common electrode 4 covering the organic light emitting layer 3 uniform. The height of the straight line part 511 is lower, and the generation possibility of the gaps of the organic light emitting layer 3 covering the straight line part 511 and the common electrode 4 is extremely low to prevent that the gaps of the organic light emitting layer 3 and the common electrode 4 generate at positions of the pixel isolation layer side walls 51 and that the water vapor and oxygen permeate into the organic light emitting layer 3. The deterioration issue of the organic light emitting layer 3 caused by the pixel isolation layer side walls 5 can be solved to avoid the short circuit of the common electrode 4 and the pixel electrode 2 for improving the display effect and promoting the usage lifetime of the OLED display element.

Specifically, the substrate 1 comprises thin film transistors, scan lines, data signal lines, and the thin film transistor comprises a gate, a semiconductor layer and source/drain. Meanwhile, the pixel electrode 2 is connected to the source/the drain of the thin film transistor. The arrangement and connection of the thin film transistors, the scan lines, the data signal lines in the substrate 1 are prior arts. No detail description is here.

Material of the pixel isolation layer 5 is Silicon Nitride. The pixel isolation layer 5 is manufactured by a plasma Chemical Vapor Deposition (CVD) process, and apertures of the pixel isolation layer 5 are manufactured by an etching process. Furthermore, the lower the component ratio of the Silicon Nitride material is, the faster the etching rate becomes. The pixel isolation layer 5 is composed by stacking a plurality of Silicon Nitride layers with various component ratios for forming the desired appearance for the pixel isolation layer side wall 51.

Alternatively, the pixel electrode 2 can be employed as the cathode of the OLED display element, and the common electrode 4 can be employed as the anode of the OLED display element. Under such circumstance, material of the pixel electrode 2 is metal oxide with high work function, such as Indium Tin Oxide (ITO), Indium zinc oxide (IZO) and etc; material of the common electrode 4 is metal with high electric conductivity and low work function, such as argent (Ag), magnesium (Mg), aluminum (Al), lithium (Li), aurum (Au), nickel (Ni) or Calcium (Ca). The pixel electrode 2, i.e. the anode functions for light path transmission, and the common electrode 4, i.e. the cathode functions for light path reflection.

Alternatively, the pixel electrode 2 can be employed as the cathode of the OLED display element, and the common electrode 4 can be employed as the anode of the OLED display element. Under such circumstance, material of the pixel electrode 2 is metal with high electric conductivity and low work function, such as Ag, Mg, Al, Li, Au, Ni or Ca; material of the common electrode 4 is metal oxide with high work function, such as ITO, IZO and etc. The pixel electrode 2, i.e. the cathode functions for light path reflection, and the common electrode 4, i.e. the anode functions for light path transmission.

Specifically, the organic light emitting layer 3 comprises a Hole Injection Layer, a Hole Transporting Layer, an light emitting layer, an Electron Transport Layer and an Electron Injection Layer, which has no difference from prior art. No detail description is here.

In conclusion, in the OLED display element of the present invention, on one hand, the inorganic material is employed to form the pixel isolation layer to tremendously reduce the water vapor and oxygen diffused from the pixel isolation layer side wall to the organic light emitting layer, and on the other hand, the pixel isolation layer side wall positions the straight line part and the curved part from top to bottom, and the height of the straight line part is smaller than the height of the curved part. At least, the included angle between a tangent plane where the portion of the curved part is and the substrate is smaller than 85° to make the thicknesses of the organic light emitting layer covering the pixel isolation layer side walls and the common electrode covering the organic light emitting layer uniform to prevent that the gaps of the organic light emitting layer and the common electrode generate at positions of the pixel isolation layer side walls and that the water vapor and oxygen permeate into the organic light emitting layer. The deterioration issue of the organic light emitting layer caused by the pixel isolation layer side walls can be solved to avoid the short circuit of the common electrode and the pixel electrode, i.e. the cathode and the anode of the OLED display element for improving the display effect and promoting the usage lifetime of the OLED display element.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. An OLED display device, comprising:
a substrate;
a plurality of pixel areas arranged in array on the substrate, and each pixel area comprises a pixel electrode, an organic light emitting layer and a common electrode sequentially stacked on the substrate;
a pixel isolation layer having a plurality of apertures, and the pixel isolation layer isolates each pixel area from other pixel areas, and the aperture is formed with pixel isolation layer side walls around, and each aperture corresponds to one pixel area;
wherein the pixel electrode and the organic light emitting layer are inside the aperture, and the organic light emitting layer covers the pixel isolation layer side walls, and the common electrode covers the organic light emitting layer and an upper surface of the pixel isolation layer;
material of the pixel isolation layer is inorganic material, and the pixel isolation layer side wall comprises a straight line part, and a curved part connected to the straight line part from top to bottom; the straight line part is perpendicular with the substrate, and a height of the straight line part is smaller than a height of the curved part, and at least, an included angle between a tangent plane where a portion of the curved part is and the substrate is smaller than 85°.

2. The OLED display element according to claim 1, wherein the curved part recesses inward relative to the pixel isolation layer.

3. The OLED display element according to claim 1, wherein the curved part embosses outward relative to the pixel isolation layer.

4. The OLED display element according to claim 1, wherein material of the pixel isolation layer is Silicon Nitride.

5. The OLED display element according to claim 4, wherein the pixel isolation layer is composed by stacking a plurality of Silicon Nitride layers with various component ratios.

6. The OLED display element according to claim 5, wherein the pixel isolation layer is manufactured by a plasma CVD process, and apertures of the pixel isolation layer are manufactured by an etching process.

7. The OLED display element according to claim 1, wherein the pixel electrode is an anode of the OLED display element, and the common electrode is a cathode of the OLED display element.

8. The OLED display element according to claim 7, wherein material of the pixel electrode is metal oxide with high work function, and material of the common electrode is metal with high electric conductivity and low work function.

9. The OLED display element according to claim 1, wherein the pixel electrode is a cathode of the OLED display element, and the common electrode is an anode of the OLED display element.

10. The OLED display element according to claim 9, wherein material of the pixel electrode is metal with high electric conductivity and low work function, and material of the common electrode is metal oxide with high work function.

11. An OLED display element, comprising:
a substrate;
a plurality of pixel areas arranged in array on the substrate, and each pixel area comprises a pixel electrode, an organic light emitting layer and a common electrode sequentially stacked on the substrate;
a pixel isolation layer having a plurality of apertures, and the pixel isolation layer isolates each pixel area from other pixel areas, and the aperture is formed with pixel isolation layer side walls around, and each aperture corresponds to one pixel area;
wherein the pixel electrode and the organic light emitting layer are inside the aperture, and the organic light emitting layer covers the pixel isolation layer side walls, and the common electrode covers the organic light emitting layer and an upper surface of the pixel isolation layer;
material of the pixel isolation layer is inorganic material, and the pixel isolation layer side wall comprises a straight line part, and a curved part connected to the straight line part from top to bottom; the straight line part is perpendicular with the substrate, and a height of the straight line part is smaller than a height of the curved part, and at least, an included angle between a tangent plane where a portion of the curved part is and the substrate is smaller than 85°;
wherein the curved part recesses inward relative to the pixel isolation layer;
wherein material of the pixel isolation layer is Silicon Nitride;
wherein the pixel isolation layer is composed by stacking a plurality of Silicon Nitride layers with various component ratios.

12. The OLED display element according to claim 11, wherein the pixel isolation layer is manufactured by a plasma CVD process, and apertures of the pixel isolation layer are manufactured by an etching process.

13. The OLED display element according to claim 11, wherein the pixel electrode is an anode of the OLED display element, and the common electrode is a cathode of the OLED display element.

14. The OLED display element according to claim 13, wherein material of the pixel electrode is metal oxide with high work function, and material of the common electrode is metal with high electric conductivity and low work function.

15. The OLED display element according to claim 11, wherein the pixel electrode is a cathode of the OLED display element, and the common electrode is an anode of the OLED display element.

16. The OLED display element according to claim 15, wherein material of the pixel electrode is metal with high electric conductivity and low work function, and material of the common electrode is metal oxide with high work function.
